(19) United States
(12) Patent Application Publication
(10) Pub. No.: US 2026/0129802 A1
(43) Pub. Date: May 7, 2026

(54) AIR GUIDE COVER AND ELECTRONIC DEVICE

(71) Applicant: Delta Electronics (Shanghai) Co.,Ltd., Shanghai (CN)

(72) Inventors: Jie ZHAO, Shanghai (CN); Yingjue LI, Shanghai (CN); Le LIANG, Shanghai (CN)

(21) Appl. No.: 19/369,368

(22) Filed: Oct. 27, 2025

(30) Foreign Application Priority Data
Nov. 5, 2024 (CN) 202411573404.X

(51) Int. Cl. H05K 7/20

(52) U.S. Cl. CPC H05K 7/2039

(57) ABSTRACT

The present disclosure discloses an air guide cover and an electronic device. The air guide cover includes a heat conduction member and a first heat dissipation member forming a circumferentially surrounded space; wherein at least a part of the heat conduction member is in contact with a heating element, and the air guide cover dissipates heat of the heating element. The air guide cover of the present disclosure may act as heat sinks of the heating element, and has a large heat dissipation area and strong heat dissipation capability, and the air guide cover also has effect of directing and guiding air from the heat sink.

### CROSS-REFERENCE TO RELATED APPLICATIONS

This non-provisional application claims priority under 35 U.S.C. § 119(a) on Patent Application 202411573404.X filed in P.R. China on Nov. 5, 2024, the entire contents of which are hereby incorporated by reference.

Some references, if any, which may include patents, patent applications and various publications, may be cited and discussed in the description of this application. The citation and/or discussion of such references, if any, is provided merely to clarify the description of the present application and is not an admission that any such reference is “prior art” to the application described herein. All references listed, cited and/or discussed in this specification are incorporated herein by reference in their entireties and to the same extent as if each reference was individually incorporated by reference.

### BACKGROUND OF THE PRESENT DISCLOSURE

### 1. Field of the Present Disclosure

The present disclosure relates to a power electronic system and its heat dissipation technology, and particularly, relates to an air guide cover and an electronic device.

### 2. Related Art

With sharp demand for computing power and power density in the industries such as cloud computing and artificial intelligence, a higher requirement for efficiency and dynamic performance of the power supply system is put forward. The vertical power supply system architecture has attracted much attention due to advantages of good dynamic performance, high efficiency and low capacitance.

The “vertical power supply system architecture” refers to a stack layout that the power supply module and the load are perpendicular to a circuit board, and arranged separately on a top surface and a bottom surface of the circuit board, and in such case, projections of the power supply module and the load on the circuit board are at least partially overlapped. As shown in FIG. 1, the existing “vertical power supply system architecture” is generally to provide a load 301′ (such as, a processor) on a top surface of an OAM board 300′, and provide a plurality of power supply modules 200′ on a bottom surface of the OAM board 300′ for supplying power to the load 301′. Moreover, a projection of the plurality of power supply modules 200′ on a plane of the OAM board is located within a range of a projection of the load on the plane of the OAM board. To improve strength of the OAM board 300′, reinforcing ribs 400′ and 500′ may also be disposed above and below the OAM board 300′, respectively. A heating power is large due to operation of the load, and a heat sink 600′ (such as, a fin heat sink) may also be arranged above the load 301′ for timely dissipating heat of the load 301′, the heat sink 600′ has an area as large as possible, but its projection on the plane of the OAM plate is located within the OAM board and has a certain height, and the possible maximum heat dissipation space of the heat sink 600′ is all spaces over the OAM board. A device combined by the OAM board 300′, the load 301′, the plurality of power supply modules 200′ and the heat sink 600′ is referred to as “an OAM module” (the sign is M1′ in the figure). To enhance rigidity of the OAM board and prevent it from wrapping and deformation, “an OAM module” may further include reinforcing ribs disposed above and below the OAM board 300′. High-speed signals may be transmitted through a connector (not shown) between the OAM module M1′ and the system board (not shown) to establish communication connection. As for the common AI server, eight OAM modules may be configured on one system board.

However, the vertical power supply system architecture also proposes a huge challenge to heat dissipation of the power supply module: the power supply module faces the problem of high heat dissipation requirement, and large difficulty in heat dissipation. Generally, supplying power to one load requires 10 to 30 power supply modules, and these power supply modules are often centrally arranged below the OAM board, and have a large power density, a high heat flux density and high heat dissipation requirement. However, due to the requirement for transmission quality of the high-speed signals between the OAM module and the system board, the distance between the OAM board and the system board is small (5 to 8 mm according to Open Computing Project (OCP) standard), and the power supply modules are provided on a lower surface of the OAM board, such that a distance between the power supply modules and the system board is narrower, and it is impossible to arrange a fin heat sink between the power supply modules and the system board; moreover, when a plurality of OAM modules are provided on one system board, a clearance between the two adjacent OAM modules in a width direction of the server is usually 1 to 2 mm, a space between the OAM modules is also too narrow, and it is impossible to arrange the fin heat sink of the power supply modules; furthermore, the power supply modules provided on the bottom surface of the OAM board are surrounded by reinforcing ribs around, the top of the reinforcing ribs and the connector is in contact with the OAM board, and the bottom thereof is in contact with the system board, so the heat dissipation space around the power supply modules is not only narrow, but also closed, and there is large difficulty in heat dissipation. The width direction of the server is a direction perpendicular to an incoming air direction within a plane parallel to an upper surface of the OAM board. That is, when the air guide cover is a square wind tunnel, the direction perpendicular to sidewalls of the air guide cover is the width direction of the server. Moreover, the power supply modules are completely blocked by two large connectors in the incoming air direction of the OAM board, causing that the incoming air almost cannot blow to position of the power supply modules, and there is large difficulty in heat dissipation. The power supply modules face the problem of high heat dissipation requirement but large difficulty in heat dissipation.

### SUMMARY OF THE PRESENT DISCLOSURE

An object of the present disclosure is to provide an air guide cover and an electronic device not occupying the heat dissipation space of the heat sink while can satisfy heat dissipation requirement of the power supply module in a narrow closed space.

In order to achieve the above object, the present disclosure provides an air guide cover, including: a heat conduction member and a first heat dissipation member forming a circumferentially surrounded space; wherein at least a part of the heat conduction member is in contact with a heating element, and the air guide cover dissipates heat of the heating element.

According to some aspects of the invention, in a vertical power supply architecture, the air guide cover of the invention may act as a heat sink of the power supply module, thereby satisfying heat dissipation requirement of the power supply module in a narrow closed space.

According to some aspects of the present disclosure, a heating element may be thermally connected to the air guide cover of the present disclosure, such that a thermal channel is formed from the heating element to the air guide cover, and the air guide cover is arranged around the heating element circumferentially. Heat of the heating element may be transferred to the air guide cover through thermal interface materials, diffused using the air guide cover, and taken away when an incoming air blows to the air guide cover. The air guide cover may act as a heat sink of the heating element, and has a large heat dissipation area and strong heat dissipation capability; the air guide cover also has effect of directing and guiding air from the heat sink for load. The air guide cover of the present disclosure circumferentially surrounding the heating element may further have the technical effect that the incoming air may directly blow to the heating element and other peripheral heat sources (in the case of not blocked by other components), thereby further enhancing heat dissipation capability.

According to some aspects of the present disclosure, in some electronic devices of the present disclosure, a heating element may be at least one power supply module, at least one load may be disposed above the power supply module, and the power supply module may supply power to the at least one load. The power supply module is not limited to be located inside the air guide cover, and the air guide cover may also not surround or partially surround the power supply module. For example, in the case that the power supply module is inserted and mounted perpendicular to the OAM board or bent after inserting and mounting when it is inserting type packaged, the air guide cover may also not surround or partially surround the power supply module. Heat of the power supply module may be transferred to the air guide cover through the thermal interface material, the air guide cover diffuses the heat, and the incoming air blows to the air guide cover to take heat away. The technical effects produced by the present disclosure are: except for the inherent effect of directing and guiding air from the heat sink for load as an air guide cover, the air guide cover also has the effect of dissipating heat of the heating element such as the power supply module, and as a heat sink of the heating element, has a large heat dissipation area and strong heat dissipation capability; heat of the power supply module may be dissipated through the peripheral air guide cover, so it is unnecessary to groove on the OAM board or the system board, thus not affecting layout and wiring of the OAM board and the system board, also not producing additional wrapping stress on the OAM board or the system board, and also not causing wrapping and deformation of the OAM board or the system board; meanwhile, since the two side panels of the air guide cover are arranged at an outer side of the OAM board, and the air guide cover itself is mounted externally to the load heat sink, as a heat sink of the heating element (such as, the power supply module), the air guide cover does not occupy the maximum potential heat dissipation space of the load heat sink, and satisfies heat dissipation requirement of the power supply module within a narrow space without reducing heat dissipation capability of the load.

Additional aspects and advantages of the present disclosure will be in part set forth in the following description, and in part will be obvious from the description, or can be learned by practice of the present disclosure.

### BRIEF DESCRIPTION OF THE DRAWINGS

The exemplary embodiments will be described in details with reference to the accompanying drawings, through which the above, other features and advantages of the present disclosure will become more apparent.

FIG. 1 is a structural diagram of formation of an OAM module in the existing vertical power supply system architecture, where it further shows the heat dissipation path of the upward heat dissipation solution utilizing 3D VC.

FIG. 2A is a structural diagram of an air guide cover in a first embodiment of the present disclosure.

FIG. 2B shows a variation of the air guide cover shown in FIG. 2A.

FIG. 3A shows a variation where the air guide cover shown in FIG. 2A does not surround heating elements.

FIG. 3B shows a variation where the air guide cover shown in FIG. 2B does not surround heating elements.

FIG. 4A is a structural diagram of an air guide cover in a second embodiment of the present disclosure.

FIG. 4B shows a variation of an air guide cover shown in FIG. 4A.

FIG. 5A is a structural diagram of an air guide cover in a third embodiment of the present disclosure.

FIG. 5B shows a variation of the air guide cover shown in FIG. 5A.

FIG. 6A is a structural diagram of an air guide cover in a fourth embodiment of the present disclosure.

FIG. 6B shows a variation of the air guide cover shown in FIG. 6A.

FIG. 7 is a structural diagram of an air guide cover in a fifth embodiment of the present disclosure.

FIG. 8 is a structural diagram of an air guide cover in a sixth embodiment of the present disclosure.

FIG. 9 is a structural diagram of an air guide cover in a seventh embodiment of the present disclosure.

FIG. 10 is a structural diagram of an assembly of an electronic device in a first preferable embodiment of the present disclosure.

FIG. 11 is a structural diagram of an electronic device in a second preferable embodiment of the present disclosure.

FIG. 12 is a structural diagram of an electronic device in a third preferable embodiment of the present disclosure.

FIG. 13 is a structural diagram of an electronic device in a fourth preferable embodiment of the present disclosure.

FIG. 14 is a structural diagram of an electronic device in a fifth preferable embodiment of the present disclosure.

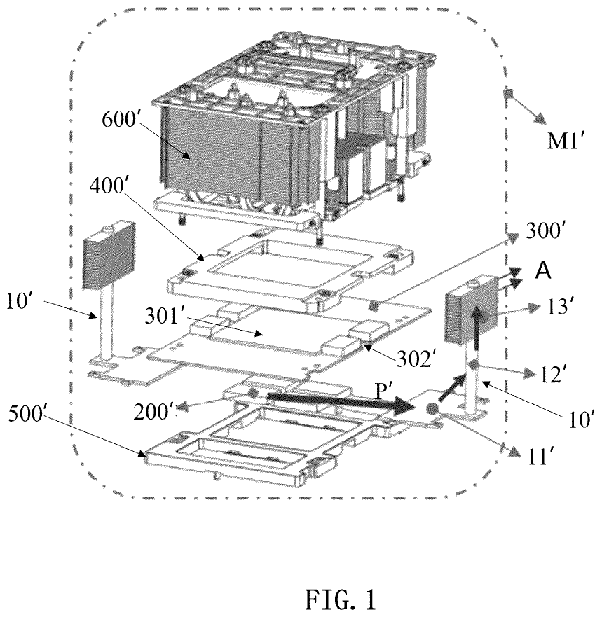

### DETAILED EMBODIMENTS OF THE INVENTION

The exemplary embodiments will now be described more fully with reference to the accompanying drawings. The exemplary embodiments can, however, be implemented in various forms, and should not be construed as being limited to the embodiments set forth herein; rather, these embodiments are provided so that the invention will be thorough and complete, and will fully convey the concept of the exemplary embodiments to those skilled in the art. In the drawings, the same reference numerals denote the same or similar structure, thus their detailed description will be omitted.

When introducing elements or constituting parts or the like described and/or illustrated here, the terms “one”, “a (an)”, “the”, “said” and “at least one” represent one or more elements or constituting parts or the like. The terms “include”, “comprise” and “have” represent an open and inclusive meaning, and also refer to other elements or constituting parts or the like in addition to the listed elements or constituting parts or the like. The term “connection” represents direct connection or indirect connection (i.e., there is also other element or constituting part between the two elements or constituting parts, such as, including but not limited to air, etc.) between two elements or constituting parts. Moreover, the terms “first”, “second” and the like in the claims are only used as reference signs, rather limiting the number of the objects.

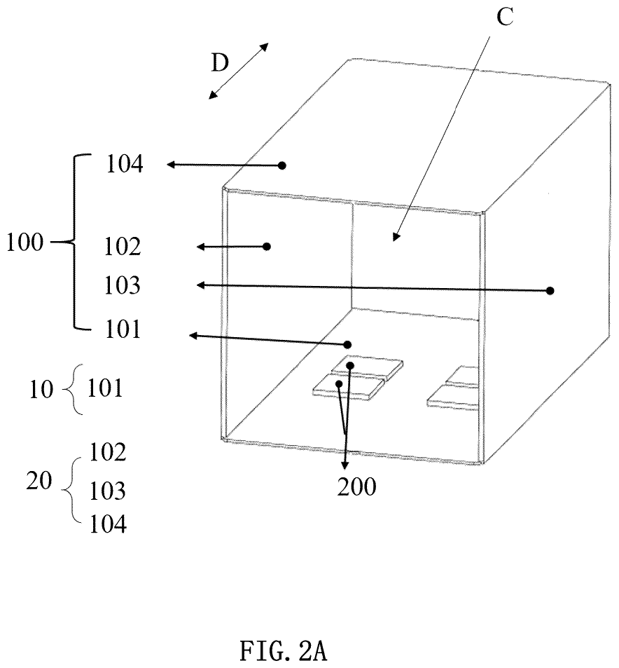

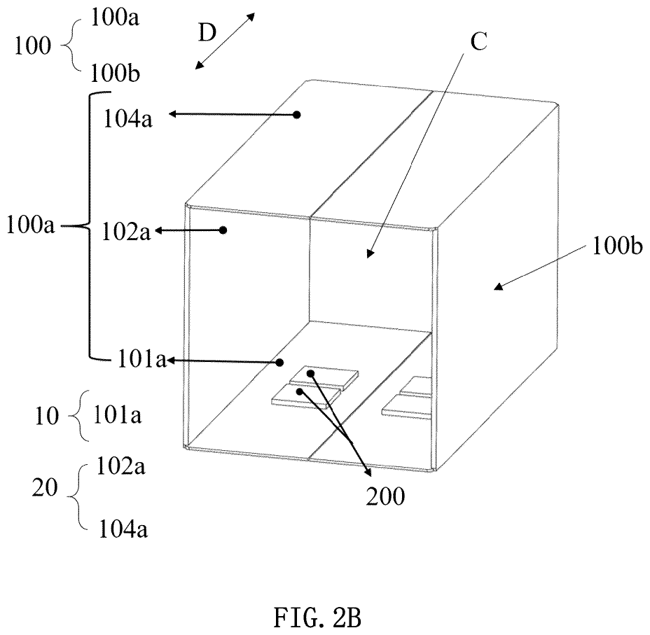

As shown in FIG. 2A, it shows a structure of an air guide cover 100 in a first embodiment of the present disclosure. The air guide cover 100 may include a heat conduction member 10 and a first heat dissipation member 20 forming a circumferentially surrounded space C. At least a part of the heat conduction member 10 is configured to contact with a heating elements 200, and the air guide cover 100 is used for dissipating heat of the heating elements 200.

In the present disclosure, it can be understood that “the heat dissipation member” and “the heat conduction member” may be all heat conduction components or heat dissipation components. The terms such as “the heat dissipation member”, “the heat dissipation component” and the like may be understood to be a portion or a component that can directly make heat exchange with the environment; the terms such as “the heat conduction member”, “the heat conduction component” and the like may be understood to be a portion or a component connected between the heat source (e.g., the heating element) and the heat dissipation component (or the heat dissipation member).

In the present disclosure, “the heating element” may include but not limited to the heat source such as a power supply module, and the like.

In some embodiments of the present disclosure, the heat conduction member 10 and the first heat dissipation member 20 may be made of the same material. Of course, it can be understood that the heat conduction member 10 and the first heat dissipation member 20 may also be made of different materials, but the present disclosure is also not limited thereto.

In the embodiment of FIG. 2A, the air guide cover 100 may be integrally manufactured. Moreover, the manufactured air guide cover 100 may be a square cylindrical shape, i.e., including one bottom 101, two sides 102 and 103 and one top 104 circumferentially surrounded and perpendicular to a wind direction. The bottom 101 may act as the heat conduction member 10 for conducting heat, and the sides 102 and 103 and the top 104 may act as the first heat dissipation member 20 for dissipating heat.

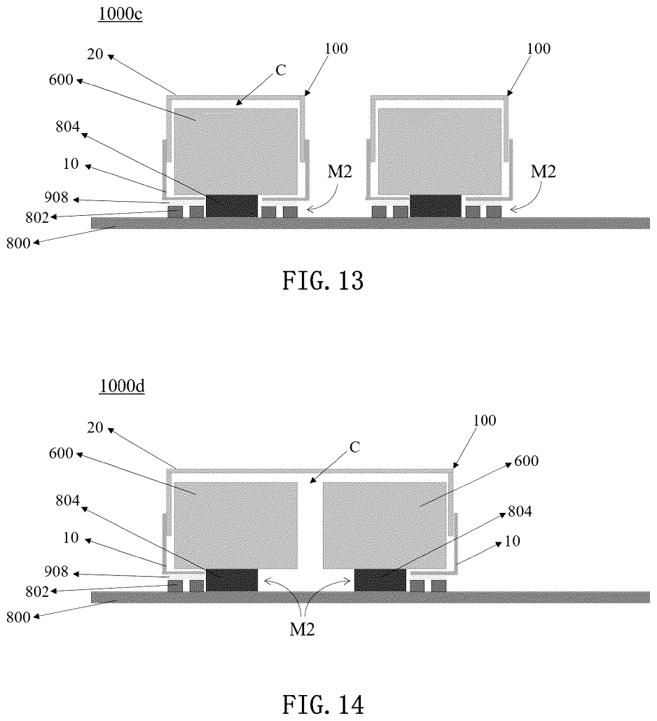

It shall be understood that the air guide cover at least includes at least two sides and one top circumferentially surrounded to form a circumferentially surrounded space. In some embodiments, the air guide cover may not be provided with the bottom. For example, a base such as an OAM board together with two sides and one top of the air guide cover surround to form a cylinder. In another embodiments, the air guide cover may also be provided with at least a part of the bottom, i.e., the bottom of the air guide cover may be a discontinuous bottom. For example, as shown in FIGS. 13 and 14, the bottom of the air guide cover is provided with a part of bottom clearance for accommodating devices such as loads. In still some embodiments, the air guide cover may also be provided with a continuous bottom, for example, as shown in FIG. 2A. The air guide cover may be provided with a part of clearance on the sides or top according to actual requirements for mounting or accommodating the devices. The air guide cover 100 may also be other shapes of cylinders, such as, hexagonal, circular cylinders and the like, to cope with different application situations.

In the embodiment of FIG. 2A, the heating elements 200 may be thermally connected to the air guide cover 100 using thermal interface materials (TIM). Moreover, the circumferentially surrounded space C formed by the air guide cover 100 may form a wind tunnel with a square longitudinal cross-section (i.e., a venting cross-section) (the longitudinal cross-section of the wind tunnel is perpendicular to a wind direction D). In this embodiment, the air guide cover 100 is arranged around the heating elements 200 circumferentially (i.e., the air guide cover 100 is arranged around the heating elements 200), heat of the heating elements 200 is transferred to the air guide cover 100 through the thermal interface materials, and may be diffused through the air guide cover 100, and an incoming air may blow to the air guide cover 100 along the wind direction D, thereby taking heat away faster.

In the embodiment of FIG. 2A, the air guide cover 100 may be made of high heat conduction materials such as copper material, diamond copper, diamond silver, aluminum alloy, and the like. More preferably, a heat conductivity coefficient of the air guide cover 100 is greater than or equal to 30 W/(m·k).

As shown in FIG. 2B, it shows a variation of the air guide cover 100 shown in FIG. 2A. In this embodiment, the air guide cover 100 is spliced by two portions, for example, relatively spliced by a first portion 100a and a second portion 100b in a C-shaped structure, i.e., “a spliced air guide cover”. Taking the structure of the first portion 100a for example, the C-shaped structure may be formed of one bottom 101a, one side 102a and one top 104a, wherein the bottom 101a may act as the heat conduction member 10 for conducting heat, and the side 102a and the top 104a may act as the heat dissipation member 20 for dissipating heat. Structure of the second portion 100b is symmetrical with that of the first portion 100a, and the details are not described here. When mounting, the first portion 100a and the second portion 100b may be pushed in and mounted from left and right sides of the OAM board, respectively, thereby splicing into a circumferentially surrounded air guide cover 100. Such “spliced air guide cover” has the characteristic of easy to mount. The “splice” may be engaged or soldered or detachably connected through screws and nuts, but the present disclosure is not limited thereto.

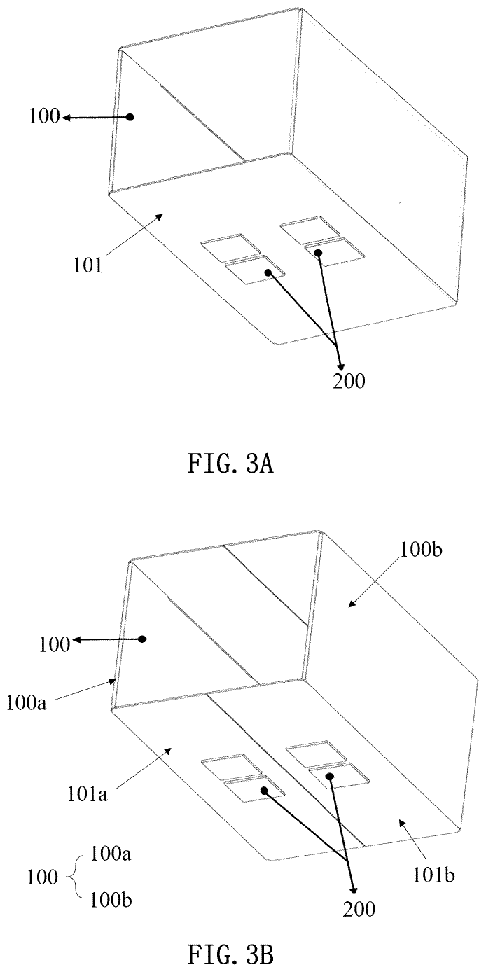

In the embodiments of FIGS. 2A and 2B, at least a part of a top surface of the heat conduction member 10 (e.g., a top surface of the bottom 101 in FIG. 2A or a top surface of the bottom 101a in FIG. 2B) is in contact with bottom surfaces of the heating elements 200 for conducting heat. However, in some other embodiments of the present disclosure, it is also possible to conduct heat through at least a part of a bottom surface of the heat conduction member 10 in contact with top surfaces of the heating elements 200, as shown in FIGS. 3A and 3B. That is, the air guide cover 100 may also not surround the heating elements 200, i.e., the heating elements 200 are arranged below or on side faces of the air guide cover 100. For example, as shown in FIG. 3A, the heating elements 200 may be arranged on a lower surface of the bottom 101 of the integrated air guide cover 100, or as shown in FIG. 3B, the heating elements 200 may be arranged on a lower surface of the bottom 101a of the first portion 100a and a lower surface of the bottom 101b of the second portion 100b of the spliced air guide cover 100. Such embodiments are mainly applicable to the case that the heating device is inserted and mounted perpendicular to the OAM board or bent after inserting and mounting when it is an inserting type device. The OAM board is located on an upper surface of the bottom of the air guide cover, and is connected to the heating device on the lower surface of the bottom of the air guide cover through inserting and mounting. Through such implementation, heat of the heating elements 200 is transferred to the air guide cover 100 through the thermal interface materials, and then diffused through the air guide cover 100, and an incoming air may blow to the air guide cover 100 along the wind direction D, thereby taking heat away faster.

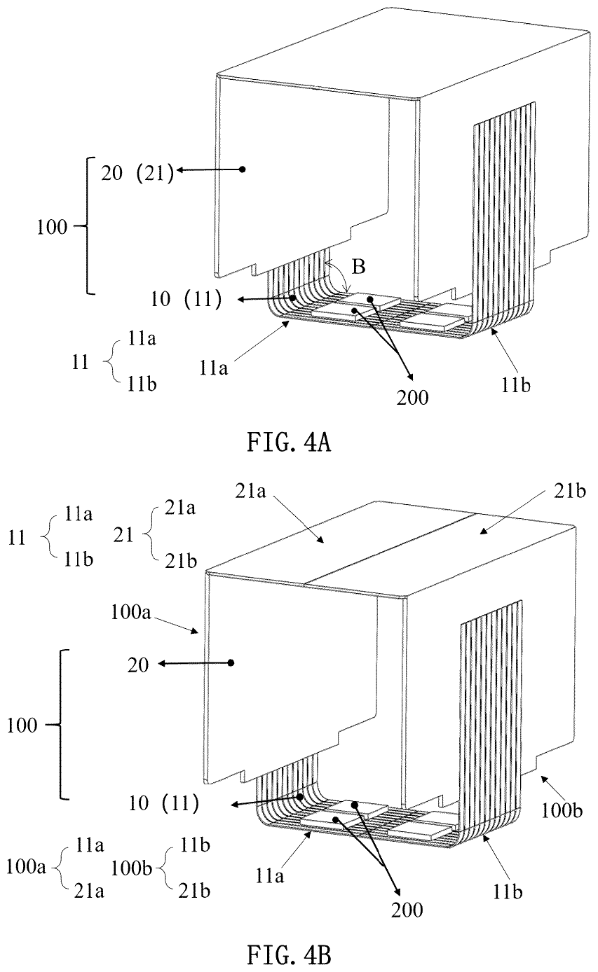

As shown in FIG. 4A, it shows a structure of an air guide cover 100 in a second embodiment of the present disclosure. The difference from the first embodiment is that a first heat dissipation member 20 of the air guide cover 100 in the second embodiment includes a first component 21 in an inverted U-shaped structure, a heat conduction member 10 includes a second component 11, which is bent and has a bending angle B, and the first component 21 is connected to the second component 11.

In the present disclosure, the heat conduction member 10 may be at least one of a vapor chamber (i.e., VC), a heat conduction sheet, a cold plate and a heat pipe, but the present disclosure is not limited thereto.

In the embodiment of FIG. 4A, the first heat dissipation member 20 may be integrally manufactured, i.e., “an integrated heat dissipation structure”. The integrated structure has advantage of simple and convenient in processing and manufacturing.

In the embodiment of FIG. 4A, for example, the second component 11 of the heat conduction member 10 is heat pipes, i.e., using the heat pipes as a heat conduction component. Moreover, the second component 11 may include a first portion 11a and a second portion 11b in a L-shaped structure bent by a plurality of heat pipes, and the first portion 11a and the second portion 11b may be spliced into a U-shaped structure, i.e., “a spliced heat conduction structure”. Heating elements 200 may be provided on an upper surface of a horizontal bending portion of the first portion 11a and/or the second portion 11b of the L-shaped structure. A vertical bending portion of the first portion 11a and the second portion 11b of the L-shaped structure is connected to the first component 21. The bending angle B bent between the horizontal bending portion and the vertical bending portion of the first portion 11a and the second portion 11b of the L-shaped structure may be approximately a right angle, i.e., 90°. The bending part between the horizontal bending portion and the vertical bending portion of the first portion 11a and the second portion 11b of the L-shaped structure is an arc shape.

As shown in FIG. 4B, it shows a variation of the air guide cover 100 shown in FIG. 4A. The difference from the “integrated heat dissipation structure” of FIG. 4A is that a first heat dissipation member 20 of the air guide cover 100 of FIG. 4B is “a spliced heat dissipation structure”, which has the advantage of convenient in disassembly and assembly to facilitate maintenance during use. That is, a first component 21 of the first heat dissipation member 20 includes a first portion 21a and a second portion 21b in an inverted L-shaped structure, and the first portion 21a and the second portion 21b may be spliced to form an inverted U-shaped structure. The “splice” may be engaged or soldered or detachably connected through screws and nuts, but the present disclosure is not limited thereto.

In the embodiment of FIG. 4B, a second component 11 of the heat conduction member 10 may be also “a spliced heat conduction structure”, i.e., including a first portion 11a and a second portion 11b in a L-shaped structure, and the first portion 11a and the second portion 11b may be spliced into a U-shaped structure.

In the embodiment of FIG. 4B, the whole air guide cover 100 may be spliced by two portions, for example, relatively spliced by a first portion 100a and a second portion 100b in a C-shaped structure, i.e., “a spliced air guide cover”. The first portion 100a in the C-shaped structure may be assembled by the first portion 21a of the first component 21 and the first portion 11a of the second component 11; the second portion 100b in the C-shaped structure may be assembled by the second portion 21b of the first component 21 and the second portions 11b of the second component 11. When mounting with the OAM module, the first portion 100a and the second portion 100b may be pushed in and mounted from left and right sides of the OAM module, respectively, thereby splicing into a circumferentially surrounded air guide cover 100. Such “spliced air guide cover” has the characteristics of convenient in disassembly and assembly, and easy to maintain.

In some other embodiments, the embodiments of FIGS. 4A and 4B may make further following variation or change. For example, the second component 11 may be directly bent into a U-shaped structure by a plurality of heat pipes, and the heating elements 200 may be provided on an upper surface or a lower surface of the bottom part of the U-shaped structure, but the present disclosure is not limited thereto.

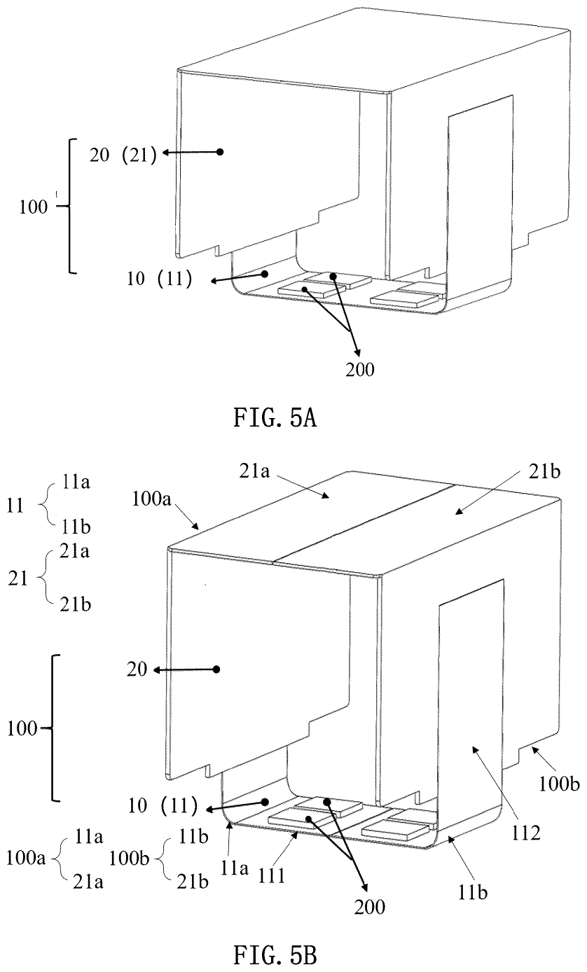

As shown in FIG. 5A, it shows a structure of an air guide cover 100 in a third embodiment of the present disclosure. The difference from the embodiment of FIG. 4A is that a second component 11 included in a heat conduction member 10 of the air guide cover 100 of FIG. 5A may be a U-shaped structure and integrally manufactured, i.e., “an integrated heat conduction structure”. Heating elements 200 may be provided on an upper surface of a bottom part of the U-shaped structure, and a side part of the U-shaped structure is connected to a first component 21. The second component 11 may be a vapor chamber (i.e., VC), i.e., using the vapor chamber as a heat conduction component. The first component 21 included in the first heat dissipation member 20 of the air guide cover 100 may be a U-shaped structure and integrally manufactured, i.e., “an integrated heat dissipation structure”. Heat of the heating elements 200 may be transferred to the VC as the heat conduction component through the thermal interface materials, and then rapidly transferred to the first heat dissipation member 20 as the heat dissipation component through a high heat diffusion capability of the VC, heat is diffused on the heat dissipation component, and an incoming air blows to the heat dissipation component to take heat away.

As shown in FIG. 5B, it shows a variation of the air guide cover 100 shown in FIG. 5A. The difference from the embodiment of FIG. 5A is that a heat conduction member 10 of the air guide cover 100 of FIG. 5B is “a spliced heat conduction structure”, and a first heat dissipation member 20 is “a spliced heat dissipation structure”. For example, a first component 21 of the first heat dissipation member 20 includes a first portion 21a and a second portion 21b in an inverted L-shaped structure, and the first portion 21a and the second portion 21b may be spliced to form an inverted U-shaped structure. A second component 11 of the heat conduction member 10 includes a first portion 11a and a second portion 11b in a L-shaped structure bent by the VC, and the first portion 11a and the second portion 11b may be spliced to form a U-shaped structure. Heating elements 200 are provided on an upper surface of a bottom part 111 of the U-shaped structure, and a side part 112 of the U-shaped structure is connected to the first portion 11a and the second portion 11b of the first component 21, respectively.

In the embodiment of FIG. 5B, the whole air guide cover 100 is spliced by two portions, for example, relatively spliced by a first portion 100a and a second portion 100b in a C-shaped structure, i.e., “a spliced air guide cover”. The first portion 100a in the C-shaped structure may be assembled by the first portion 21a of the first component 21 and the first portion 11a of the second component 11; the second portion 100b in the C-shaped structure may be assembled by the second portion 21b of the first component 21 and the second portion 11b of the second component 11. When mounting, the first portion 100a and the second portion 100b may be pushed in and mounted from left and right sides of the OAM board, thereby splicing into a circumferentially surrounded air guide cover 100. Such “spliced air guide cover” has the characteristic of easy to mount.

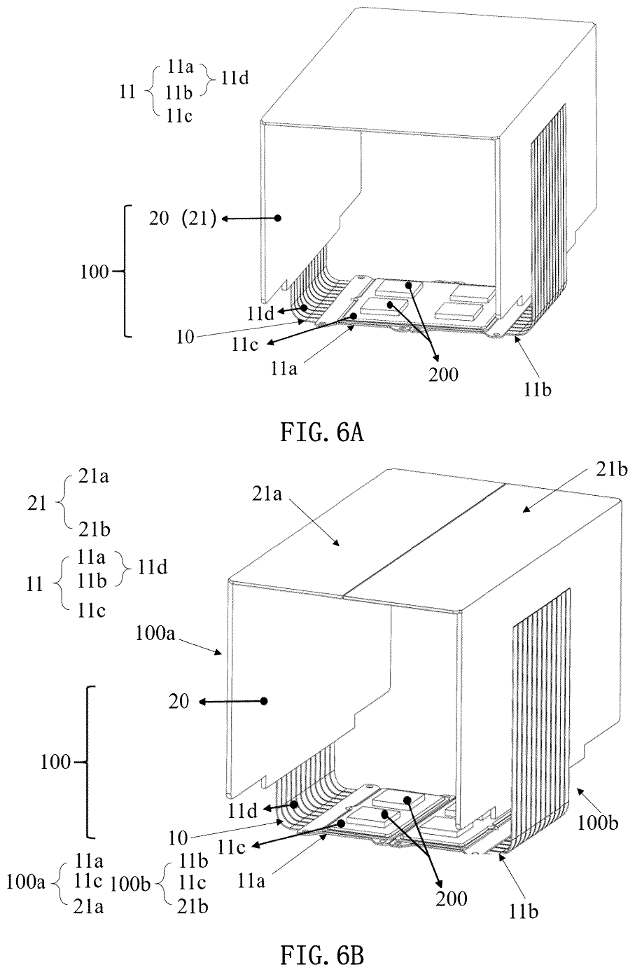

As shown in FIG. 6A, it shows a structure of an air guide cover 100 in a fourth embodiment of the present disclosure. The difference from the embodiment of FIG. 6A is that a second component 11 included in a heat conduction member 10 of the air guide cover 100 of FIG. 6A includes a vapor chamber (i.e., VC) 11c and heat pipes 11d, i.e., using a combination of the vapor chamber 11c and the heat pipes 11d as a heat conduction component. The second component 11 includes a first portion 11a and a second portion 11b in a L-shaped structure bent by a plurality of heat pipes 11d, and the first portion 11a and the second portion 11b may be spliced into a U-shaped structure. One vapor chamber 11c is provided on an upper surface of a bottom part of the U-shaped structure, and in contact with heating elements 200. The plurality of heat pipes 11d in the first portion 11a and the second portion 11b are connected to the vapor chamber 11c and the first heat dissipation member 20, respectively. For example, a lower surface of the vapor chamber 11c may be connected to a first end of the plurality of heat pipes 11d, and a second end of the plurality of heat pipes 11d is connected to the first heat dissipation member 20. Heat of the heating elements 200 may be transferred to the vapor chamber 11c through the thermal interface materials, may be rapidly spread depending on super high thermal diffusion capability of the VC, and then transferred to the first heat dissipation member 20 through the heat pipes 11d, and an incoming air blows to the first heat dissipation member 20 to take heat away. This embodiment has stronger thermal diffusion capability and faster heat dissipation, and may support a heating device (or a power supply module) with a larger power density.

As shown in FIG. 6B, it shows a variation of the air guide cover 100 shown in FIG. 6A. The difference from the embodiment of FIG. 6A is that a heat conduction member 10 of the air guide cover 100 of FIG. 6B is “a spliced heat conduction structure”, and a first heat dissipation member 20 is “a spliced heat dissipation structure”. For example, a first component 21 of the first heat dissipation member 20 includes a first portion 21a and a second portion 21b in an inverted L-shaped structure, and the first portion 21a and the second portion 21b may be spliced to form an inverted U-shaped structure. A second component 11 of the heat conduction member 10 includes a first portion 11a and a second portion 11b in a L-shaped structure bent by a plurality of heat pipes 11d, and the first portion 11a and the second portion 11b may be spliced into a U-shaped structure. Upper surfaces of first ends of the plurality of heat pipes 11d in the first portion 11a and the second portion 11b are connected to a vapor chamber 11c, respectively, and second ends of the plurality of heat pipes 11d in the first portion 11a and the second portion 11b are connected to the first portion 21a and the second portion 21b of the first heat dissipation member 20, respectively. Heating elements 200 are provided on an upper surface of the vapor chamber 11c. Heat of the heating elements 200 may be transferred to the vapor chamber 11c through the thermal interface materials, may be rapidly spread depending on super high thermal diffusion capability of the VC, and then transferred to the first heat dissipation member 20 through the heat pipes 11d, and an incoming air blows to the first heat dissipation member 20 to take heat away.

In the embodiment of FIG. 6B, the whole air guide cover 100 may be spliced by two portions, for example, relatively spliced by a first portion 100a and a second portion 100b in a C-shaped structure, i.e., “a spliced air guide cover”. The first portion 100a in the C-shaped structure may be assembled by the first portion 21a of the first component 21 and the first portion 11a of the second component 11 as well as the vapor chamber 11c thereon, and the second portion 100b in the C-shaped structure may be assembled by the second portion 21b of the first component 21 and the second portion 11b of the second component 11 as well as the vapor chamber 11c thereon. When mounting, the first portion 100a and the second portion 100b may be pushed in and mounted from left and right sides of the OAM board, thereby splicing into a circumferentially surrounded air guide cover 100. Such “spliced air guide cover” has the characteristic of easy to mount.

In some other embodiments, the embodiments of FIGS. 6A and 6B may further make the following variation or change. For example, the second component 11 may be directly bent into a U-shaped structure by a plurality of heat pipes, one vapor chamber 11c may be provided on an upper surface or a lower surface of a bottom part of the U-shaped structure, and the heating elements 200 are in contact with the vapor chamber 11c, but the present disclosure is not limited thereto.

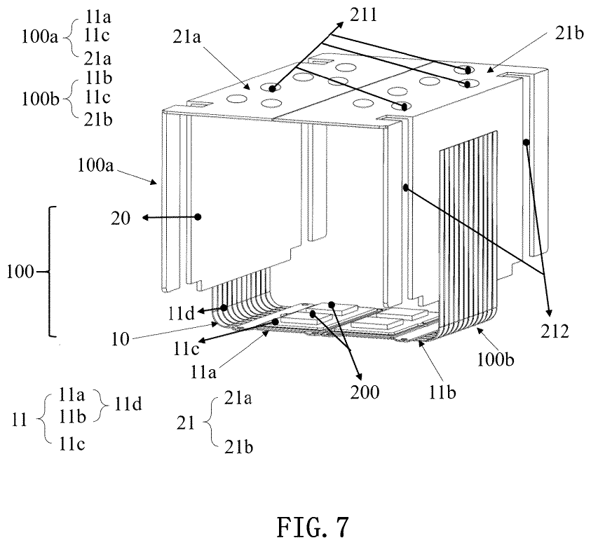

As shown in FIG. 7, it shows a structure of an air guide cover 100 in a fifth embodiment of the present disclosure. The difference from the embodiment of FIG. 6B is that a first component 21 of a first heat dissipation member 20 of the air guide cover 100 of FIG. 7 is further provided with an avoidance hole 211 and/or an avoidance gap 212 to achieve the object of structure avoidance. For example, the avoidance hole 211 arranged on the top of a first portion 21a and a second portion 21b in an inverted L-shaped structure can satisfy the requirement for avoidance of the heat pipe structure of the heat sink or other structures. To facilitate modular design and mount of the OAM module, side faces of the first portion 21a and the second portion 21b in the inverted L-shaped structure may be locally vacant to form the avoidance gap 212 for designing and mounting a handle or other structures. The avoidance hole or avoidance gap of the air guide cover is not limited to the structure in this embodiment, and may also be applied to the structure of the air guide cover in other embodiments.

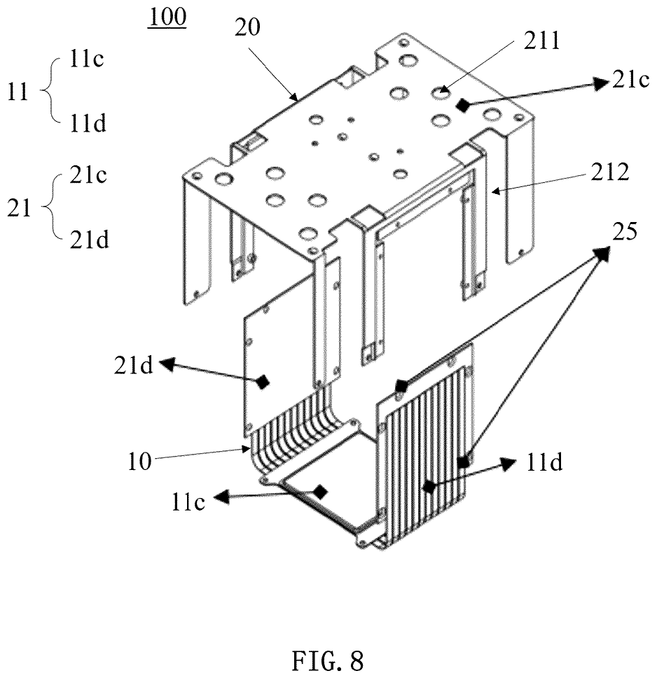

As shown in FIG. 8, it shows a structure of an air guide cover 100 in a sixth embodiment of the present disclosure. In the embodiment of FIG. 8, a first component 21 of a first heat dissipation member 20 of the air guide cover 100 includes a body member 21c and a side panel member 21d, and the side panel member 21d may be detachably connected or directly spliced with the body member 21c through a detachable connector such as screws 25. Advantage of such structure is convenient in disassembly and assembly. Optionally, the side panel member 21d is connected to the heat conduction member 11 in advance., the body member 21c, for example, may be an inverted U-shaped structure and may be provided with an avoidance hole 211 and an avoidance gap 212 thereon. A second component 11 of a heat conduction member 10 of the air guide cover 100 uses a combination of a plurality of heat pipes 11d and one vapor chamber 11c as a heat conduction component, the plurality of heat pipes 11d may be directly bent to form a U-shaped structure, the vapor chamber 11c is provided on an upper surface of a bottom part of the U-shaped structure, and a side part of the U-shaped structure is connected to the side panel member 21d.

In some other embodiments, the embodiment of FIG. 8 may further make following variation or change. For example, the second component 11 of the heat conduction member 10 may be “a heat conduction structure” shown in FIG. 6A, or “a spliced heat conduction structure” shown in FIG. 6B, or the vapor chamber 11c may be provided on a lower surface of the bottom part of the U-shaped heat conduction structure, but the present disclosure is not limited thereto.

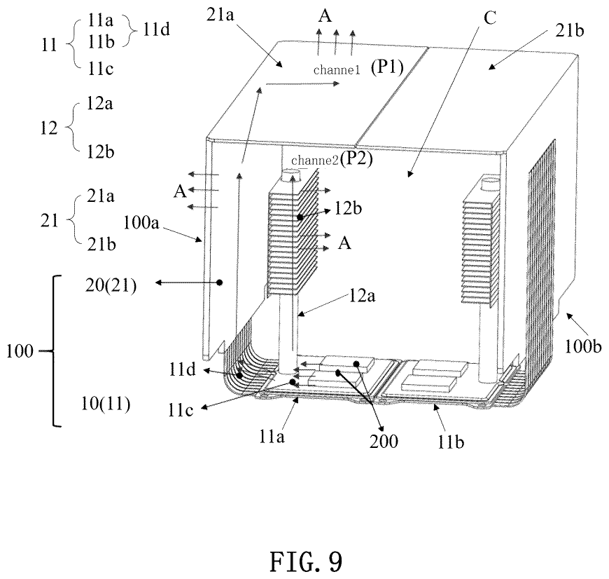

As shown in FIG. 9, it shows a structure of an air guide cover 100 in a seventh embodiment of the present disclosure. In the embodiment of FIG. 9, the air guide cover 100, for example, may be “a spliced air guide cover” shown in FIG. 6B, and has “a spliced heat conduction structure” and “a spliced heat dissipation structure” shown in FIG. 6B, and the difference from FIG. 6B is that the air guide cover 100 further includes a second heat dissipation member 12 connected to a heat conduction member 10, such that heat of the heating elements may be dissipated to air A simultaneously through channels 1 and 2 so as to further enhance heat dissipation capability. The second heat dissipation member 12 is located within a space C, and includes a heat pipe 12a and a fin 12b, a bottom end of the heat pipe 12a is connected to a vapor chamber (i.e., VC) 11c, and the fin 12b is arranged at a top end of the heat pipe 12a. Heat emitted from heating elements 200 may be dissipated via a first heat dissipation channel P1 formed by the heat conduction member 10 (e.g., including the vapor chamber 11c and the heat pipe 11d) and the first heat dissipation member 20, and heat emitted from the heating elements 200 may be further dissipated via a second heat dissipation channel P2 formed by the heat conduction member 10 (e.g., including the vapor chamber 11c) and the second heat dissipation member 12. In such way, heat dissipation capability is enhanced by setting two heat dissipation channels, and heat dissipation requirement of the heating element with a larger power may be satisfied.

More specifically, the structure of the air guide cover 100 of FIG. 9 is particularly applicable to systems with a vertical power supply architecture having an extremely high power density, and takes heat of the heating elements 200 away using two heat dissipation channels (i.e., channels 1 and 2). As shown in FIG. 9, the two heat dissipation channels may share the vapor chamber 11c (i.e., the VC), for example, may have an opening on an upper cover plate of the VC to solder the heat pipe 11a such that steam channels of both are communicated to form a 3D VC structure, and a surface of a lower cover plate of the VC is directly connected to the heat pipe 11d of the air guide cover 100 as a heat conduction component.

As shown in FIG. 9, the heat dissipation channel 2 may be a heat dissipation channel of the 3D VC structure (i.e., a heat dissipation channel formed by a second heat sink), which is from the heating elements 200 (such as, the power supply modules) to the VC (i.e., 11c) of the 3D VC structure, then to the fin 12b at a top end of the heat pipe 12a through the heat pipe 12a, and finally transferred to air A via the fin 12b. Heat generated by the heating elements 200 (such as, the power supply modules) may be transferred to an upper surface of the VC (i.e., 11c) of the 3D VC structure through the thermal interface materials between the power supply module and the VC, and rapidly diffused within the whole VC depending on high efficient heat uniformizing capability of the VC. A vapor chamber of the VC (i.e., 11c) is communicated with a vapor chamber of the heat pipe 12a, and heat is rapidly transferred to the heat pipe 12a from the VC (i.e., 11c), rapidly transferred to a condensing end of the heat pipe, i.e., a top end of the heat pipe, depending on high efficient heat conduction capability of the heat pipe 12a, and then taken away by an incoming air through the fin 12b soldered at the condensing end of the heat pipe.

As shown in FIG. 9, the heat dissipation channel 1 is a heat dissipation channel of the air guide cover 100 (i.e., a heat dissipation channel formed by a first heat sink), which is from the heating elements 200 (such as, the power supply modules) to the VC (i.e., 11c) of the air guide cover 100 as a heat conduction component, then transferred to the heat dissipation component (i.e., 21) of the air guide cover via the heat pipe 11d of the air guide cover 100 as the heat conduction component, and finally transferred to air A. Heat of the heating elements 200 (such as, the power supply modules) may be transferred to the VC (i.e., 11c) as the heat conduction component through the thermal interface materials, spread depending on super high thermal diffusion capability of the VC, and then transferred to the heat dissipation component (i.e., 21) through the heat pipe 11d, and an incoming air blows to the heat dissipation component to take heat away.

In the above embodiments of the present disclosure, when the heat conduction component uses heat pipes, a thickness of the heat pipes is less than 0.5 mm, and, an ultra-thin heat pipe with a thickness of 0.3 to 0.5 mm may be used. The “thickness” refers to a thickness of an outer profile of the heat pipes. When a plurality of OAM modules are provided on a system board, a clearance between the adjacent two OAM modules in a width direction of the server is usually 1 to 2 mm. The ultra-thin heat pipe has strong heat dissipation capability and a small size, and may satisfy heat dissipation requirement of the power supply module within the 1 mm narrow clearance between OAM boards of the adjacent two OAM modules. The width direction of the server is perpendicular to an incoming air direction D within a plane parallel to an upper surface of the OAM board. The number of heat pipes is arbitrary, and the more the number is and the stronger the thermal diffusion capability of the heat conduction member is, the higher the heating power of the heating elements may be supported.

In the above embodiments of the present disclosure, the at least a part of the second component 11 (e.g., a horizontal bending portion of the first portion 11a and the second portion 11b in the L-shaped structure) of the heat conduction member 10 in contact with the heating elements 200 has a thickness less than 8 mm, greater than or equal to 5 mm, and less than or equal to 8 mm. Due to limitation of the requirement for transmission quality of high-speed signals between the OAM modules and the system board, a distance between the OAM board and the system board is relatively small (5 to 8 mm according to Open Computing Project (OCP) standard), and in such way, the above requirement can be satisfied, a space of the power supply modules can be ensured, and the requirement for transmission quality of high-speed signals between the OAM modules and the system board can also be satisfied. It shall be understood that when the air guide device is applied to a non-standard customized server, a thickness of the at least a part of the second component 11 of the heat conduction member 10 in contact with the heating elements 200 is not limited thereto, and may be set according to actual needs.

In the above embodiments of the present disclosure, materials of the first component 21 of the first heat dissipation member 20 and/or the second component 11 of the heat conduction member 10 may be at least one of copper plate, aluminum alloy plate, graphene film, and a composite material of diamond and metal. When the heat dissipation member and/or the heat conduction member select the above materials with a high heat conductivity coefficient, it is possible to enable the air guide cover to have strong thermal diffusion capability, thereby satisfying heat dissipation requirement of the heating device.

In the present disclosure, “the heat conduction member” or “the heat conduction component” may be at least one of a vapor chamber, a heat conduction sheet and a heat pipe, and the material may be at least one of copper, aluminum alloy, graphene, and a composite material of diamond and metal. “The heat dissipation member” or “the heat dissipation component” may be at least one of copper plate, aluminum alloy plate, graphene film, and a composite material of diamond and metal. Of course, it shall be understood that the present disclosure is not limited thereto, and other structures or materials that can achieve heat conduction or heat dissipation are also feasible. For example, the vapor chamber (i.e., the VC) in the above embodiments of the present disclosure may also be replaced by a cold plate, a heat pipe or a heat conduction sheet, and is made of respective types of high heat conduction materials such as copper, diamond copper, diamond silver, aluminum alloy and the like. However, the heat conduction sheet has weaker thermal diffusion capability than the VC, and is not applicable to scenario of high heat flux density heat sources; the water-cooled plate takes heat of the heat source away depending on water flow, and is applicable to scenario of high heat flux density, but it requires to externally connect components such as cooling water source, water pump, pipelines and control elements, and the system is complicated.

In the above embodiments of the present disclosure, the heat conduction member and the heat dissipation member may use the same heat dissipation structure, such as, one of a vapor chamber, a heat conduction sheet, a cold plate or a heat pipe, and the heat conduction member and the heat dissipation member may be integrally formed. The heat conduction member and the heat dissipation member may also use different heat dissipation structures, i.e., the heat conduction member and the heat dissipation member are at least two structures of a vapor chamber, a heat conduction sheet, a cold plate or a heat pipe. For example, the heat conduction member is a heat pipe, and the heat dissipation member is a metal plate. It shall be noticed that the heat conduction member and the heat dissipation member may select suitable heat dissipation structures according to needs, and the present disclosure is not limited thereto.

In the above embodiments of the present disclosure, connection between the heat conduction member and the heat dissipation member may be tin soldering or soldering with other solders, may also be sintered silver gel, and may also be coating with high heat conduction thermal interface materials and tightening with screws. Advantages of the way of soldering and sintered silver gel are reliable connection, small interface thermal resistance, strong heat transfer capability, but it is impossible to disassemble, and inconvenient in mounting. If connecting using the thermal interface materials, the interface thermal resistance is large, and the heat transfer capability is weak, but disassembly and assembly are convenient. In the present disclosure, connection between the heat conduction member and the heat dissipation member may be flexibly selected according to application scenarios.

The present disclosure provides an electronic device, and mainly includes a heating element 200 and the air guide cover 100 according to any of the above embodiments. The heating element 200 is in contact with a heat conduction member 10 of the air guide cover 100.

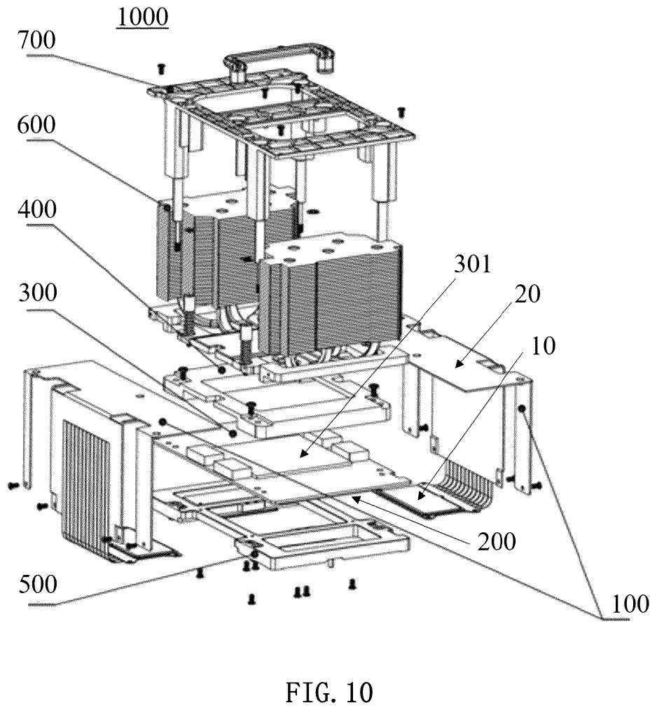

As shown in FIG. 10, it shows an assembly structure of an electronic device 1000 in a first embodiment of the present disclosure. In the embodiment of FIG. 10, the air guide cover 100 of the electronic device 1000 may be “a spliced air guide cover” shown in FIG. 6B or FIG. 7 (the present disclosure is not limited thereto), and the electronic device 1000 may further include a first circuit board 300 and a load 301. The heating element 200 may include at least one power supply module disposed on a bottom surface of the first circuit board 300. The power supply module may be directly soldered to the bottom surface of the first circuit board 300, and may also be connected to the first circuit board 300 through an adapter board. The load 301 may be located on a top surface of the first circuit board 300. These power supply modules may supply power to the load 301. Moreover, bottom surfaces of these power supply modules may be in contact with a top surface of the heat conduction member 10 of the air guide cover 100. In such way, heat generated by these power supply modules may be conducted by the heat conduction member 10 of the air guide cover 100, and be dissipated through the first heat dissipation member 20 of the air guide cover 100. Heat of the heating elements 200 is transferred to the heat dissipation member 20 through the heat conduction member 10, and dissipated through the heat dissipation member 20, and finally, an incoming air gathered by the air guide cover 100 blows to the heat dissipation member 20 to take heat away. The first circuit board 300 may be, for example, an OAM board.

Continue to refer to FIG. 10, in some embodiments of the present disclosure, the electronic device 1000 may further include a heat sink 600. The heat sink 600 may be located within an air guide region (i.e., a space C shown in FIG. 2A) of the air guide cover, and the air guide cover 100 may guide air to the heat sink 600. The heat sink 600 may be, for example, a fin heat sink for timely dissipating heat of the load 301.

In some embodiments of the present disclosure, to improve strength of the first circuit board, the electronic device 1000 may further include reinforcing ribs 400 and 500 disposed above and below the first circuit board 300, respectively.

In some embodiments of the present disclosure, to facilitate modular design and mount of the OAM module, side faces of the air guide cover 100 may also be locally vacant for designing and mounting a handle 700.

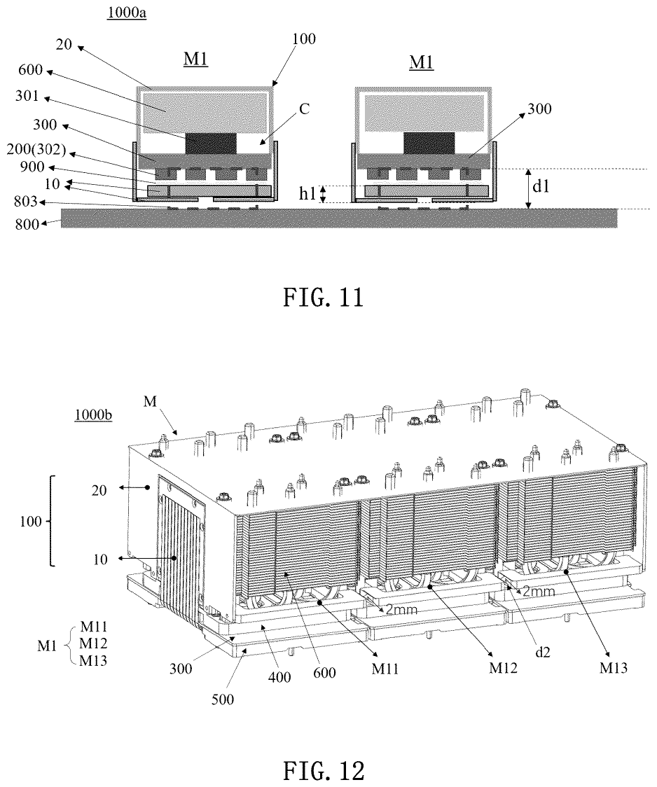

As shown in FIG. 11, it shows a structure of an electronic device 1000a in a second preferable embodiment of the present disclosure. In the embodiment of FIG. 11, a heating element 200 may include a plurality of power supply modules 302 disposed on a bottom surface of a first circuit board 300 (such as, an OAM board). Moreover, the electronic device 1000a further includes a second circuit board 800 located below a heat conduction member 10 of the air guide cover 100. The second circuit board 800 and the first circuit board 300 have a first clearance d1 therebetween, and the first circuit board 300 and the second circuit board 800 may be connected through a connector 803 within the first clearance d1. The second circuit board 800 may be, for example, a system board. The first clearance d1 is greater than or equal to 5 mm, and less than or equal to 8 mm.

In some embodiments of the present disclosure,, a thickness h1 of the heat conduction member 10 in contact with the heating element 200 may vary according to actual situations, and may be less than a difference of subtracting a height of the power supply modules 302 from the first clearance d1 between the second circuit board 800 and the first circuit board 300. In application of such as an AI server, a distance between the OAM board (i.e., the first circuit board 300) and the system board (i.e., the second circuit board 800) is 5 to 8 mm according to OCP standard, so a thickness h1 of the heat conduction member 10 in contact with the heating element 200 in the air guide cover 100 of the present disclosure may be designed to be less than 8 mm so as to conform to the relevant requirement of the OCP standard, such that a space of the power supply modules can be ensured, and the requirement for transmission quality of high-speed signals between the OAM modules and the system board can also be satisfied.

Continue to refer to FIG. 11, in some embodiments of the present disclosure, vertical projections of the power supply modules 302 and the load 301 on the first circuit board 300 are at least partially overlapped. In other embodiments, the projection of the power supply modules 302 on the first circuit board 300 is located within the projection of the load 301 on the first circuit board 300 to achieve the shortest power supply path between the power supply modules 302 and the load 301, thereby largely reducing loss of the power distribution system (PDN), and enhancing power supply efficiency of the system.

In some embodiments of the present disclosure, a first module M1 includes the first circuit board 300, the power supply modules 302 and the load 301. In other embodiments, the first module M1 (such as, the OAM module) may further include the first circuit board 300 (such as, the OAM board), the load 301, the plurality of power supply modules 302 and the heat sink 600. In other embodiments, the first module M1 (such as, the OAM module) may further include the reinforcing ribs 400 and 500 (referring to FIG. 10) above and below the first circuit board.

Continue to refer to FIG. 11, in some embodiments of the present disclosure, one second circuit board 800 may be configured with one first module M1 or a plurality of first modules M1. For example, the embodiment of FIG. 11 shows two first modules M1, the two first modules M1 are arranged at interval along a length direction of the second circuit board 800, and when there is a plurality of first modules M1, they may also be arranged in an array on the second circuit board 800. However, it shall be understood that the number and arrangement of first modules M1 configured on one second circuit board 800 are not limited thereto.

In the embodiment of FIG. 11, each first module M1 is correspondingly provided with one air guide cover 100, i.e., the power supply module 302 of each first module M1 is in contact with the heat conduction member 10 of the correspondingly provided air guide cover 100, and heat is transferred to the heat dissipation member 20 through the heat conduction member 10 for heat dissipation.

In some embodiments of the present disclosure, with respect to the inserting type or other elements for dissipating heat from the bottom surface, the air guide cover 100 of the present disclosure may also be directly connected to the bottom or the sides of the heating element 200.

As shown in FIG. 12, it shows a structure of an electronic device 1000b in a third embodiment of the present disclosure. In the embodiment of FIG. 12, at least two first modules M1 may share one air guide cover 100, i.e., in an air guide region surrounded by the air guide cover 100, the power supply module of the at least two first modules M1 is in contact with the heat conduction member of the same air guide cover 100, and heat is transferred to the heat dissipation member of the air guide cover through the heat conduction member for heat dissipation. FIG. 12 only shows three first modules M1, for example, including three first modules M11, M12 and M13 arranged by a distance d2 from left to right, and these first modules M11, M12 and M13 share one air guide cover 100. The distance d2 between the two adjacent first modules M1 is, for example, 2 mm, but the present disclosure is not limited thereto.

In other embodiments, taking the first module M11 for example, the first module M11 at least includes one first circuit board 300 (such as, OAM board), a load disposed on a top surface of the first circuit board 300, a plurality of power supply modules disposed on a bottom surface of the first circuit board 300, and a heat sink 600 disposed on the load. The first module M11 may further include reinforcing ribs 400 and 500 above and below the first circuit board 300.

Devices M after assembly of the three first modules M11, M12 and M13 (which are referred to as “M1”) shown in FIG. 12 and the air guide cover 100 may be configured on one second circuit board (not shown, such as, a system board). However, it shall be understood that the number and arrangement of the first modules M1 configured on one second circuit board are not limited thereto.

Taking the common AI server for example, eight OAM modules may be configured on one system board and arranged in two rows, and along a width direction of the server, an interval between the OAM boards of the adjacent two OAM modules may be 2 mm. In some possible designs, the at least two OAM modules may share one air guide cover. A plurality of heating elements are arranged on the at least two OAM modules, and heat of the plurality of heating elements is transferred to the heat dissipation component through the heat conduction component of the air guide cover, and then taken away through an incoming air.

Referring to FIGS. 12 and 9, in some embodiments of the present disclosure, the electronic device 1000b may further include a second heat dissipation member 12 shown in FIG. 9. In such way, heat emitted from the heating elements 200 (such as, a plurality of power supply modules disposed on a bottom surface of the first circuit board 300) may be dissipated via a first heat dissipation channel P1 (referring to “P1” shown in FIG. 9) formed by the heat conduction member 10 and the first heat dissipation member 20; heat emitted from the heating element 200 (such as, a plurality of power supply modules disposed on a bottom surface of the first circuit board 300) may be further dissipated via a second heat dissipation channel P2 (referring to “P2” shown in FIG. 9) formed by the heat conduction member 10 and the second heat dissipation member 12 (referring to “12”shown in FIG. 9).

As shown in FIG. 13, it shows a structure of an electronic device 1000c in a fourth preferable embodiment of the present disclosure. In the embodiment of FIG. 13, the electronic device 1000c includes at least one heating element (such as, a power supply module 802), at least one load 804, at least one heat sink 600, at least one air guide cover 100 and a second circuit board 800 (such as, a system board). The power supply module 802 and the load 804 are both arranged on the second circuit board 800, and projections of the power supply module 802 and the load 804 on a plane where the second circuit board 800 is located are not overlapped., the number of the power supply module 802 and the load 804 may be plural, and the power supply module 802 supplies power to the load 804.

In the embodiment of FIG. 13, the at least one power supply module 802, the at least one load 804 and the at least one heat sink 600 form one second module M2. Moreover, each second module M2 is correspondingly provided with one air guide cover 100. In each second module M2, the heat sink 600 is located above the load 804, and is within an air guide region C surrounded by the correspondingly provided air guide cover 100 for dissipating heat of the corresponding load 804. In the embodiment of FIG. 13, one heat sink 600 may be correspondingly provided with one air guide cover 100, and this embodiment has advantages of flexible in design, simple and convenient. In the embodiment of FIG. 13, the heat conduction member 10 of the corresponding air guide cover 100 may be connected to the corresponding power supply module 802 through a thermal interface material 908, thereby transferring heat of the corresponding power supply module 802 to the heat conduction member 10 of the corresponding air guide cover 100, then transferring heat to the heat dissipation member 20 of the air guide cover 100, and then taking heat away through an incoming air. In this embodiment, the air guide cover 100 not only has effect of guiding and directing air from the heat sink 600, but also has effect of dissipating heat of the power supply module 802.

In some other cases, the heat sink 600 in this embodiment may not include, i.e., the second module M2 may not include the heat sink 600.

In the embodiment of FIG. 13, heat of the corresponding power supply module 802 may be transferred to the corresponding heat conduction member 10 through the thermal interface material 908.

Devices after assembly of the two second modules M2 shown in FIG. 13 and the correspondingly provided air guide cover 100 are configured on one second circuit board 800 (such as, a system board) side-by-side from left to right. However, it shall be understood that the number and arrangement of the second modules M2 configured on one second circuit board 800 are not limited thereto.

As shown in FIG. 14, it shows a structure of an electronic device 1000d in a fifth preferable embodiment of the present disclosure. The difference from the electronic device 1000c in the embodiment of FIG. 13 is that at least two second modules M2 share one air guide cover 100. In the embodiment of FIG. 14, the two second modules M2 are configured on one second circuit board 800 (such as, a system board) side-by-side from left to right. However, it shall be understood that the number and arrangement of the second modules M2 configured on one second circuit board 800 are not limited thereto.

The two second modules M2 in the embodiment of FIG. 14 share one air guide cover 100, i.e., two heat sinks 600 of the two second modules M2 are arranged in an air guide region C surrounded by one air guide cover 100, power supply modules 802 corresponding to the two loads 804 of the two second modules M2 are in contact with the heat conduction member 10 of the same air guide cover 100 (for example, in FIG. 14, the corresponding power supply module 802 on the left may correspondingly supply power to the load 804 in the left second module M2, and be in contact with the left heat conduction member 10 of the air guide cover 100; the corresponding power supply module 802 on the right may correspondingly supply power to the load 804 in the right second module M2, and be in contact with the right heat conduction member 10 of the air guide cover 100), and heat generated by these power supply modules 802 may be dissipated after transferring heat to the heat dissipation member 20 of the air guide cover 100 through the corresponding heat conduction member 10., in the embodiment of FIG. 14, heat of the corresponding power supply module 802 may be transferred to the corresponding heat conduction member 10 through the thermal interface material 908. The embodiment of FIG. 14 has advantage of convenient in processing and assembly.

According to some aspects of the present disclosure, in a vertical power supply architecture, heat may be diffused using the air guide cover 100 of the present disclosure as a heat sink of the power supply modules, and heat is taken away through an incoming air blowing to the air guide cover, thereby satisfying heat dissipation requirement of the power supply modules in a narrow closed space.

According to some aspects of the present disclosure, the heating element 200 may be thermally connected to the air guide cover 100 of the present disclosure, such that a thermal channel is formed from the heating element 200 to the air guide cover 100, the air guide cover 100 is arranged around the heating element 200 circumferentially, heat of the heating element 200 may be transferred to the air guide cover 100 through the thermal interface material, and diffused using the air guide cover 100, and when an incoming air blows to the air guide cover 100, heat may be taken away. As compared to the prior art, the technical effects produced by the present disclosure are: the air guide cover 100 may act as a heat sink of the heating element 200, has a large heat dissipation area and strong heat dissipation capability; the air guide cover 100 also has effect of directing and guiding air from the heat sink 600.

According to some aspects of the present disclosure, in some electronic devices of the present disclosure, the heating element 200 may be at least one power supply module, at least one load may be provided above the power supply module, and the power supply module may supply power to the at least one load. The power supply module is not limited to be located inside the air guide cover 100, and the air guide cover 100 does not surround or partially surround the power supply module. The power supply module may be the case of inserting and mounting perpendicular to the OAM board or bending after inserting and mounting when it is inserting type packaged, heat may be transferred to the air guide cover 100 through the thermal interface material, the air guide cover 100 diffuses heat, and an incoming air blows to the air guide cover 100 to take heat away. As compared to the prior art, the technical effects produced by the present disclosure are: the air guide cover 100 acts as a heat sink of the heating element 200, and has a large heat dissipation area and strong heat dissipation capability; the air guide cover 100 also has the effect of directing and guiding air from the heat sink 600; the OAM board and the system board are not grooved while not affecting layout, wiring and stress wrapping of the board; space of the heat sink fin of the load is not occupied to satisfy heat dissipation requirement of the power supply module within a narrow space.

The above exemplary embodiments of the present disclosure are illustrated and described in details. It should be understood that the present disclosure is not limited to the disclosed embodiments, rather, the present disclosure intends to cover various modifications and equivalent arrangements included in the spirit and scope of the appended claims.

What is claimed is:

1. An air guide cover, comprising:
a heat conduction member and a first heat dissipation member forming a circumferentially surrounded space;
wherein at least a part of the heat conduction member is configured to contact a heating element for dissipating heat of the heating element.

2. The air guide cover according to claim 1, wherein,
at least a part of a top surface of the heat conduction member is configured to contact a bottom surface of the heating element for conducting heat.

3. The air guide cover according to claim 1, wherein,
the first heat dissipation member comprises a first component, which is in an inverted U-shaped structure;
the heat conduction member comprises a second component, which is bent and has a bending angle, the first component connected to the second component.

4. The air guide cover according to claim 1, wherein the heat conduction member is at least one of a vapor chamber, a heat conduction sheet, a cold plate and a heat pipe.

5. The air guide cover according to claim 1, wherein the heat conduction member and the first heat dissipation member are made of the same material.

6. The air guide cover according to claim 3, wherein the first component comprises a first portion and a second portion, which are connected.

7. The air guide cover according to claim 6, wherein the first portion and the second portion of the first component are in an inverted L-shape.

8. The air guide cover according to claim 4, wherein the heat pipe is an ultra-thin heat pipe with a thickness of 0.3 to 0.5 mm.

9. The air guide cover according to claim 2, wherein the heat conduction member in contact with the heating element has a thickness less than 8 mm.

10. The air guide cover according to claim 1, wherein the air guide cover has a heat conductivity coefficient greater than or equal to 30 W/(m·k).

11. The air guide cover according to claim 3, wherein materials of the first component and/or the second component are at least one of copper, aluminum alloy, graphene, and a composite material of diamond and metal.

12. The air guide cover according to claim 3, wherein the first component comprises:
a body member;
a side panel member detachably connected to the body member, and the second component connected to the side panel member.

13. An electronic device, comprising:
a heating element;
the air guide cover according to claim 1;
wherein the heating element is in contact with the heat conduction member of the air guide cover.

14. The electronic device according to claim 13, wherein the electronic device further comprises:
a first circuit board;
a load; wherein,
the heating element comprises at least one power supply module disposed on a bottom surface of the first circuit board, the load is located on a top surface of the first circuit board, and the power supply module supplies power to the load;
a bottom surface of the at least one power supply module is in contact with a top surface of the heat conduction member.

15. The electronic device according to claim 14, wherein the electronic device further comprises:
at least one heat sink in contact with the load, and the heat sink located within an air guide region of the air guide cover, the air guide cover configured for guiding air to the heat sink.

16. The electronic device according to claim 14, wherein projections of the at least one power supply module and the load on the first circuit board are at least partially overlapped.

17. The electronic device according to claim 14, wherein a projection of the at least one power supply module on the first circuit board is located within a projection of the load on the first circuit board.

18. The electronic device according to claim 14, wherein the first circuit board, the at least one power supply module and the load form a first module, and at least two of the first modules share one air guide cover.

19. The electronic device according to claim 18, wherein the first module comprises a plurality of power supply modules disposed on the bottom surface of the first circuit board.

20. The electronic device according to claim 14, wherein the electronic device further comprises:
a second circuit board located below the heat conduction member;
wherein the second circuit board and the first circuit board have a first clearance therebetween; the first circuit board and the second circuit board are connected through a connector within the first clearance.

21. The electronic device according to claim 13, wherein the electronic device further comprises:
a second circuit board located below the heat conduction member;
wherein the heating element is disposed on the second circuit board.

22. The electronic device according to claim 20, wherein the first clearance is greater than or equal to 5 mm, and less than or equal to 8 mm.

23. The electronic device according to claim 18, wherein the electronic device further comprises:
a second circuit board located below the heat conduction member; at least two of the first modules disposed on one second circuit board.

24. The electronic device according to claim 13, wherein the electronic device further comprises:
a second heat dissipation member connected to the heat conduction member, wherein,
heat emitted from the heating element is dissipated via a first heat dissipation channel formed of the heat conduction member and the first heat dissipation member;
heat emitted from the heating element is further dissipated via a second heat dissipation channel formed of the heat conduction member and the second heat dissipation member.

25. The electronic device according to claim 14, wherein the top surface of the first circuit board and/or the bottom surface of the first circuit board are provided with reinforcing ribs.

26. The electronic device according to claim 13, wherein the electronic device further comprises:
a second circuit board located below the heat conduction member;
the heating element comprises at least one power supply module disposed on the second circuit board;
the at least one power supply module is in contact with the heat conduction member.

27. The electronic device according to claim 26, wherein the electronic device further comprises:
a load disposed on the second circuit board.

28. The electronic device according to claim 27, wherein the electronic device further comprises:
a heat sink in contact with the load and located within an air guide region of the air guide cover, the air guide cover configured for guiding air to the heat sink.

29. The electronic device according to claim 27, wherein the at least one power supply module and the at least one load form one second module, and at least two of the second modules share one air guide cover.

30. The electronic device according to claim 27, wherein the at least one power supply module and the at least one load form one second module, and each of the second modules is correspondingly provided with one air guide cover.
